(19) United States
(12) Patent Application Publication
(10) Pub. No.: US 2017/0243808 A1
(43) Pub. Date: Aug. 24, 2017

(54) JOINED BODY AND MANUFACTURING METHOD THEREOF, AND COOLING DEVICE AND ELECTRONIC EQUIPMENT USING COOLING DEVICE

(71) Applicant: FUJITSU LIMITED, Kawasaki-shi (JP)

(72) Inventors: MAKOTO YOSHINO, Isehara (JP); Takahiro Kimura, Isehara (JP); Motoaki Tani, Akashi (JP)

(73) Assignee: FUJITSU LIMITED, Kawasaki-shi (JP)

(21) Appl. No.: 15/591,511

(22) Filed: May 10, 2017

Related U.S. Application Data
(63) Continuation of application No. PCT/JP2015/081475, filed on Nov. 9, 2015.

(30) Foreign Application Priority Data
Nov. 14, 2014 (JP) 2014-232026

(51) Int. Cl. H01L 23/473; B32B 7/12; B32B 15/085; H01L 21/48; B32B 27/32; B32B 38/00; B32B 37/12; B32B 3/30; B32B 15/20

(52) U.S. Cl. CPC H01L 23/473; B32B 3/30; B32B 7/12; B32B 15/085; B32B 15/20; B32B 27/32; B32B 38/0012; B32B 37/12; H01L 21/4882; B32B 2255/06; B32B 2255/24; B32B 2307/302; B32B 2323/10; B32B 2311/12; B32B 2457/00

(57) ABSTRACT

A joined body of the embodiments is a joined body which includes copper and resin, wherein in a joint surface of the copper to the resin, a triazine thiol derivative, or the triazine thiol derivative and a silane coupling agent are bonded to a base surface and the silane coupling agent is bonded to an oxide film formed on part of the joint surface, respectively, and the copper and the resin are molecularly joined to each other. This configuration makes it possible to obtain a joined body having high reliability by molecularly joining both the base surface and the oxide film of the copper, and the resin securely and achieving a strong joint of the copper and the resin at a time of joining the copper and the resin even though the oxide film is formed on part of the joint surface of the copper.

### CROSS-REFERENCE TO RELATED APPLICATION

This application is a continuation application of International Application PCT/JP2015/081475 filed on Nov. 9, 2015 and designated the U.S., which claims the benefit of priority of the prior Japanese Patent Application No. 2014-232026, filed on Nov. 14, 2014, the entire contents of which are incorporated herein by reference.

### FIELD

The embodiments discussed herein are directed to a joined body and a manufacturing method thereof, and a cooling device and electronic equipment using the cooling device.

### BACKGROUND

A cooling device of electronic equipment circulates a coolant in a cooling plate thermally connected to an electronic component such as a CPU on a system board and transports it to a heat exchanger to radiate heat. In the cooling plate, it is necessary for a base plate and fins for heat radiation to be formed of a metal having high thermal conductivity such as copper. In contrast, thermal conductivity is not necessary for a cover and a pipe which connects adjacent cooling plates other than the base plate and the fins as a material property. Therefore, a study of replacing materials of the cover and the pipe with resin has been made. As long as this becomes possible, there is a possibility of a great contribution to reduction in weight of a liquid contact member represented by the cooling plate.

[Patent Document 1] Japanese Laid-open Patent Publication No. 09-252184

[Patent Document 2} Japanese Laid-open Patent Publication No. 2013-131595

[Patent Document 3] International Publication Pamphlet No. WO 2010/029635

In a cooling plate, there is a method of mechanically fastening an outer peripheral portion of a joint portion with a screw or a bolt with an O-ring interposed therebetween, in order to join a metallic base plate and a resinous cover. However, in this case, a plurality of screws and bolts are necessary for fastening, causing complication of a structure.

Accordingly, as a method of joining the metallic base plate and the resinous cover without using the screw or the bolt, it is considered that a base plate made of copper (copper base plate) is roughened by surface treatment to form concavities and convexities and the resinous cover (resin cover) is subjected to thermocompression bonding.

Further, it is considered that a compound which reacts with both a surface of a copper base plate and a surface of a resin cover is applied, and the thermocompression bonding is performed, and the parts are made to adhere to each other by a chemical bond. In this case, in order to impart reactivity on a copper surface, a cleaned copper base plate is subjected to immersion treatment in a reactive compound solution to form a reactive film. There is a problem that an oxide film is easily formed on the copper surface subjected to cleaning or the like in contact with air, and in a formation portion of the oxide film, formation of the reactive film becomes difficult. A technique in which the reactive film is formed on even the portion of the copper surface on which the oxide film is formed, and a uniform reactive film is formed on the copper surface to be thereafter joined to resin is awaited under the present situation.

### SUMMARY

One aspect of a joined body is a joined body which includes copper and resin, wherein in a joint surface of the copper to the resin, a triazine thiol derivative is bonded to a base surface or a silane coupling agent is bonded on the triazine thiol derivative, and the silane coupling agent is bonded to an oxide film formed on part of the joint surface, respectively, and the copper and the resin are molecularly joined to each other.

One aspect of a manufacturing method of a joined body includes molecularly joining copper in which a triazine thiol derivative, or the triazine thiol derivative and a silane coupling agent are bonded to a base surface in a joint surface and the silane coupling agent is bonded to an oxide film formed on part of the joint surface, respectively, and resin by bringing the copper and the resin in contact with each other.

One aspect of a cooling device is a cooling system including a cooling plate which includes: a copper base plate to which an electronic component is thermally connected; and a resin cover which covers above the copper base plate and in which a cooling liquid is supplied to an inner space, wherein the electronic component is cooled by circulating the cooling liquid, wherein in a joint surface of the copper base plate to the resin cover, a triazine thiol derivative, or the triazine thiol derivative and a silane coupling agent are bonded to a base surface and the silane coupling agent is bonded to an oxide film formed on part of the joint surface, respectively, and the copper base plate and the resin cover are molecularly joined to each other.

One aspect of an electronic equipment includes: a cooling device which includes a cooling plate including a copper base plate to which an electronic component is thermally connected and a resin cover which covers above the copper base plate and in which a cooling liquid is supplied to an inner space, and in which the electronic component is cooled by circulating the cooling liquid; and an electronic device which includes the electronic component, wherein in a joint surface of the copper base plate to the resin cover, a triazine thiol derivative, or the triazine thiol derivative and a silane coupling agent are bonded to a base surface and the silane coupling agent is bonded to an oxide film formed on part of the joint surface, respectively, and the copper base plate and the resin cover are molecularly joined to each other.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1A is a schematic sectional view illustrating a manufacturing method of a joined body according to a first embodiment;

FIG. 1B is a schematic sectional view illustrating the manufacturing method of the joined body according to the first embodiment, sequentially from FIG. 1A;

FIG. 1C is a schematic sectional view illustrating the manufacturing method of the joined body according to the first embodiment, sequentially from FIG. 1B;

FIG. 2A is a schematic sectional view illustrating the manufacturing method of the joined body according to the first embodiment, sequentially from FIG. 1C;

FIG. 2B is a schematic sectional view illustrating the manufacturing method of the joined body according to the first embodiment, sequentially from FIG. 2A;

FIG. 2C is a schematic sectional view illustrating the manufacturing method of the joined body according to the first embodiment, sequentially from FIG. 2B;

FIG. 3A is a schematic view illustrating a structural formula 1 of a compound in the first embodiment;

FIG. 3B is a schematic view illustrating a structural formula 2 of a compound in the first embodiment;

FIG. 3C is a schematic view illustrating a structural formula 3 of a compound in the first embodiment;

FIG. 4 illustrates an enlarged anchor portion of the joined body according to the first embodiment;

FIG. 5A is a schematic view illustrating Comparative Example 1 of the first embodiment;

FIG. 5B is a schematic view illustrating Comparative Example 2 of the first embodiment;

FIG. 5C is a schematic view illustrating Comparative Example 3 of the first embodiment;

FIG. 6A is a schematic view illustrating Comparative Example 4 of the first embodiment;

FIG. 6B is a schematic view illustrating Comparative Example 4 of the first embodiment;

FIG. 7A is a schematic view illustrating Comparative Example 5 of the first embodiment;

FIG. 7B is a schematic view illustrating Comparative Example 5 of the first embodiment;

FIG. 8A is a schematic view illustrating Comparative Example 6 of the first embodiment;

FIG. 8B is a schematic view illustrating Comparative Example 6 of the first embodiment;

FIG. 9A is a schematic view illustrating Comparative Example 7 of the first embodiment;

FIG. 9B is a schematic view illustrating Comparative Example 7 of the first embodiment;

FIG. 10A is a schematic view illustrating Comparative Example 7 of the first embodiment;

FIG. 10B is a schematic view illustrating Comparative Example 7 of the first embodiment;

FIG. 11 is a schematic view illustrating a schematic configuration of electronic equipment using a cooling device according to a second embodiment;

FIG. 12 is a sectional view illustrating a schematic configuration of a cooling plate of the cooling device according to the second embodiment;

FIG. 13 is a schematic view illustrating a specific example of the electronic equipment in FIG. 11;

FIG. 14 is a schematic view illustrating a specific example of the cooling device of the electronic equipment in FIG. 11;

FIG. 15 is a schematic view illustrating a schematic configuration of a measuring device which measures joint strength; and

FIG. 16 is a diagram illustrating a table of results of a joint strength test and a water pressure resistance test according to a second example.

FIG. 17 is a diagram illustrating a table of results of a joint strength test and a water pressure resistance test according to the comparative examples.

### DESCRIPTION OF EMBODIMENTS

Hereinafter, specific embodiments are explained in detail with reference to the drawings.

### First Embodiment

In this embodiment, a joined body of copper and resin and a manufacturing method thereof are disclosed. For convenience of explanation, a structure of the joined body is described together with the manufacturing method thereof.

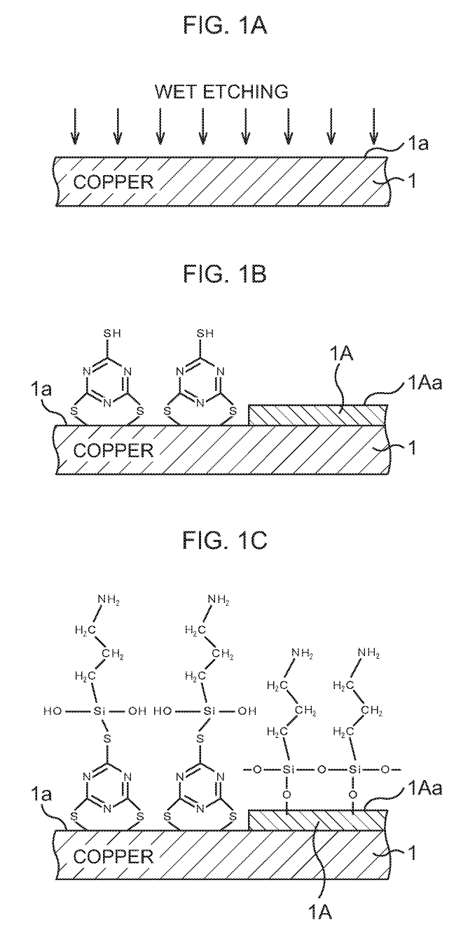

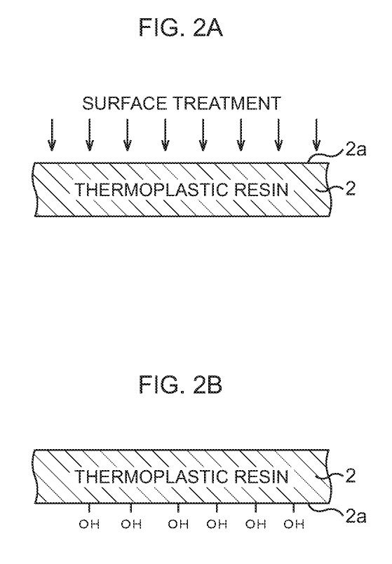

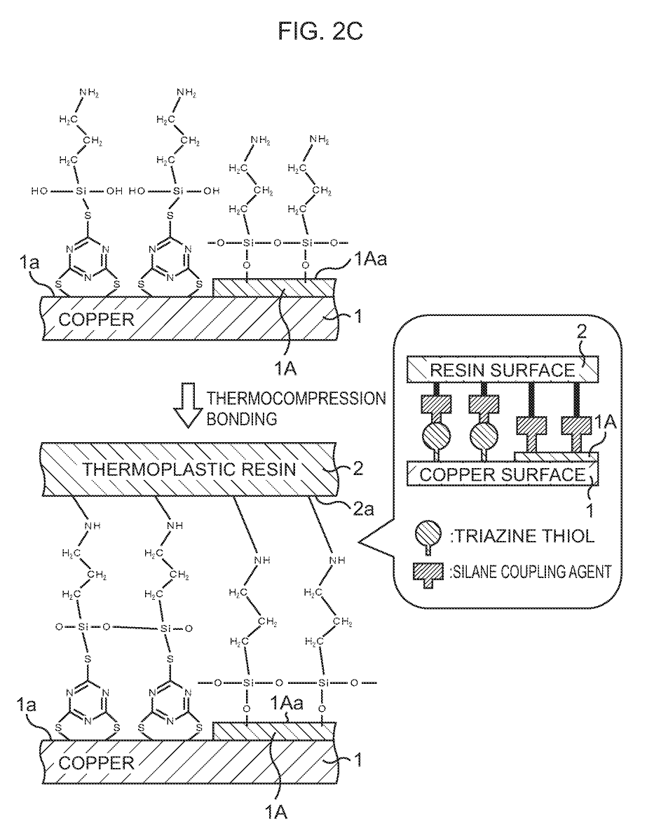

FIG. 1A to FIG. 1C and FIG. 2A to FIG. 2C are schematic sectional views illustrating the manufacturing method of the joined body according to a first embodiment in order of a process.

In this embodiment, a case where a copper plate and a resin layer are joined to each other to form the joined body is exemplified.

First, as illustrated in FIG. 1A, a base surface 1a of a copper plate 1 is subjected to surface roughening treatment.

In detail, in the base surface 1a of the copper plate 1, only a joint portion to the resin layer is exposed and the other portion is covered with an etching mask. In this state, a cupric chloride solution, a ferric chloride solution, or a sulfuric acid-hydrogen peroxide solution is used as an etching solution, and the exposed portion of the base surface 1a is roughened by wet etching. For example, concavities and convexities having a ten-point average surface roughness of 2 μm or more are formed on the exposed portion of the base surface 1a of the copper plate 1 by this surface roughening treatment. The etching mask is removed by predetermined wet treatment or the like.

By subjecting the base surface 1a of the copper plate 1 to surface roughening, minute concavities and convexities are formed on the base surface 1a, resulting in an increase in an area in contact with the later-described resin layer. This results in obtaining a strong and secure molecular joint between the copper plate 1 and the resin layer.

Sequentially, as illustrated in FIG. 1B, the base surface 1a of the surface-roughened copper plate 1 is subjected to reactive film treatment.

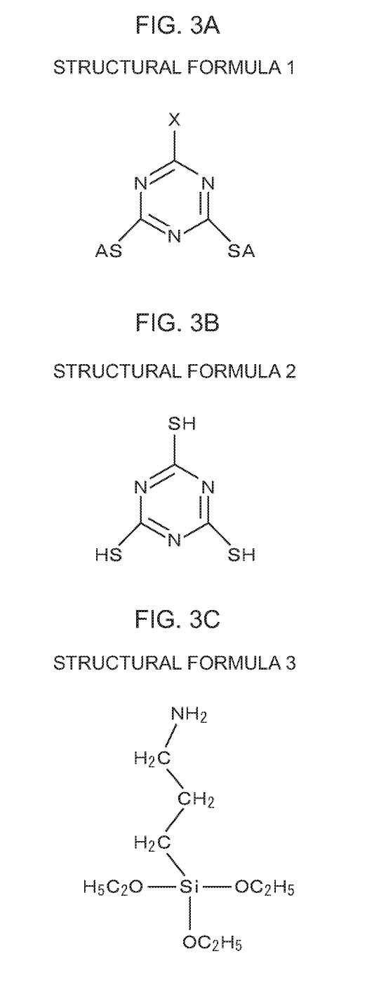

In detail, after surface cleaning of the surface-roughened copper plate 1, the base surface 1a is subjected to the reactive film treatment using a treatment solution containing a material for forming a reactive film. As the material for forming a reactive film, a triazine thiol derivative having a triazine skeleton, which is represented by a structural formula 1 in FIG. 3A, is used. In the structural formula 1, X represents at least either of NR₂ and SA. R represents at least any one of a hydrogen atom, a methyl group, an ethyl group, a propyl group, and a phenyl group, and A represents at least any one of a hydrogen atom, a Li atom, a Na atom, a K atom, a Rb atom, and a Cs atom. As long as a compound having the triazine skeleton is the triazine thiol derivative represented by the structural formula 1, it is not particularly limited and can be selected appropriately depending on purposes. In terms of excellent reactivity, triazine thiol represented by a structural formula 2 in FIG. 3B, specifically, 2,4,6-trimercapto-1,3,5-triazine monosodium salt or the like is suitable.

Contact with air easily causes surface oxidation on the copper plate. For example, in the copper plate subjected to surface cleaning or the like, a copper oxide film is formed on part of a joint surface of the copper plate to the resin layer by the contact with air. In this embodiment, a copper oxide film 1A is formed on part of the base surface 1a of the copper plate 1. To a portion (exposed portion of base surface 1a) where the copper oxide film 1A is not formed in the base surface 1a of the copper plate 1, triazine thiol is bonded by the surface roughening treatment to form a triazine thiol film. On the other hand, on a portion where the copper oxide film 1A is formed in the base surface 1a of the copper plate 1, the triazine thiol film is not formed even though the surface roughening treatment is performed.

Sequentially, as illustrated in FIG. 1C, the copper plate 1 subjected to the reactive film treatment is subjected to silane coupling agent treatment.

In detail, the silane coupling agent treatment is performed by immersing the copper plate 1 in an aqueous solution of a silane coupling agent represented by a structural formula 3 in FIG. 3C to form a film of the silane coupling agent. The silane coupling agent is a compound constituted of organic matter and silicon and has two or more types of different reactive groups of a reactive group which performs a chemical bond to an inorganic material and a reactive group which performs a chemical bond to an organic material in a molecule, thereby serving as an intermediary which combines the organic material and the inorganic material which do not normally combine together. The silane coupling agent may be bonded to only the portion where the copper oxide film 1A is formed in a surface of the copper plate 1, but in this embodiment, the silane coupling agent is bonded to both a surface 1Aa of the copper oxide film 1A and triazine thiol bonded to the base surface 1a on which the copper oxide film 1A is not formed.

As the silane coupling agent, the one including at least one type selected from a group constituted of an amino group, a mercapto group, an epoxy group, an imidazole group, and a dialkylamino group in a molecular is desirable. The copper plate 1 after being immersed in the aqueous solution of the silane coupling agent is preferably subjected to drying processing. A drying temperature is preferably about 70° C. to 150° C. and more preferably about 90° C. to 130° C. A drying time is preferably about 5 minutes to 120 minutes and more preferably about 10 minutes to 60 minutes.

As illustrated in FIG. 2A, a surface 2a of a resin layer 2 is subjected to surface treatment.

As a material of the resin layer 2, for example, one type selected from polyamide, polyethylene terephthalate, polycarbonate, polyethylene, polypropylene, polyphenylene sulfide, and the like is used. Because the material of the resin layer 2 is subjected to thermocompression bonding in a joint to the copper plate 1, it is desirably a thermoplastic resin which softens near the melting point of resin.

A hydroxyl group or a carboxyl group, or both of them are formed on the surface 2a by the surface treatment for the surface 2a of the resin layer 2. When the hydroxyl group or the carboxyl group exists on the surface 2a of the resin layer 2, a reaction with an amino group of the silane coupling agent or a mercapto group of triazine thiol is accelerated, resulting in a secure molecular joint of the resin and the copper in an anchor portion. As the surface treatment for forming a hydroxyl group on the surface 2a, there are ultraviolet (UV) ozone treatment, oxygen plasma treatment, alkaline cleaning, boiling treatment, and so on. As the surface treatment for forming a carboxyl group on the surface 2a, there are the UV ozone treatment, the oxygen plasma treatment, corona discharge treatment, and so on.

Instead of performing the above-described surface treatment, a resin layer having a hydroxyl group or a carboxyl group, or both of them on a surface may be used.

Sequentially, as illustrated in FIG. 2B, a joint surface (base surface 1a and surface 1Aa of copper oxide film 1A) of the copper plate 1 and the surface 2a of the resin layer 2 are opposed to each other.

Sequentially, as illustrated in FIG. 2C, a joint is made by thermocompression bonding the copper plate 1 and the resin layer 2.

In detail, the joint surface (base surface 1a and surface 1Aa of copper oxide film 1A) of the copper plate 1 and the surface 2a of the resin layer 2 are subjected to the thermocompression bonding. It is preferable from the viewpoint of a joining property that A thermocompression bonding temperature is set to about 100° C. to 300° C., a joint pressure is set to about 0.1 MPa to 3 Mpa, and a thermocompression bonding time is set to about 30 seconds to 120 seconds.

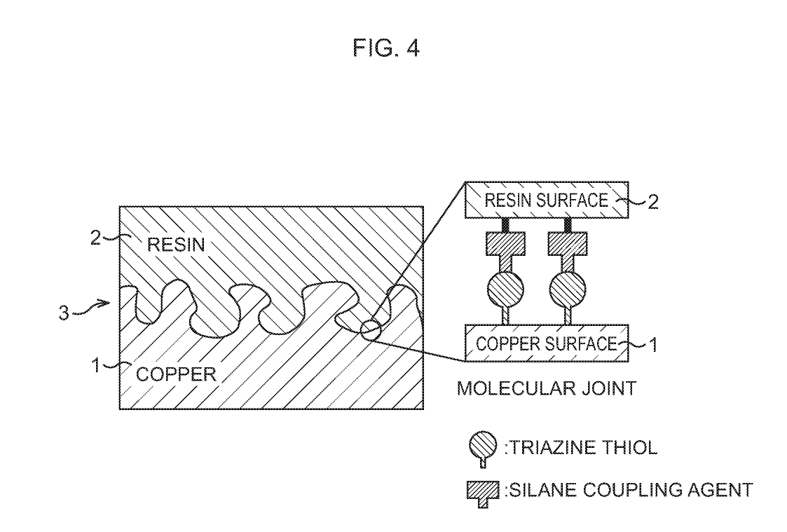

By to the above-described thermocompression bonding, amino groups (—NH₂) located at ends on the joint surface (base surface 1a and surface 1Aa of copper oxide film 1A) of the copper plate 1 and hydroxyl groups (—OH) located at ends on the surface 2a of the resin layer 2 are bonded to each other by a dehydration reaction. At this time, as illustrated in FIG. 4, an anchor portion 3 is formed by the resin of the surface 2a of the resin layer 2 entering the concavities and the convexities on the base surface 1a of the copper plate 1. In the anchor portion 3, the strong and secure molecular joint is obtained between the copper and the resin by an anchor effect of the concavities and the convexities on the base surface 1a.

Thus, between the copper plate 1 and the resin layer 2, a perfect molecular joint in the entire surface of the joint surface, namely both the base surface 1a of the copper plate 1 and the surface 2a of the resin layer 2, and the surface 1Aa of the copper oxide film 1A of the copper plate 1 and the surface 2a of the resin layer 2 is obtained, and very high joint strength is achieved.

### COMPARATIVE EXAMPLES

Here, comparative examples of this embodiment are explained.

### Comparative Example 1

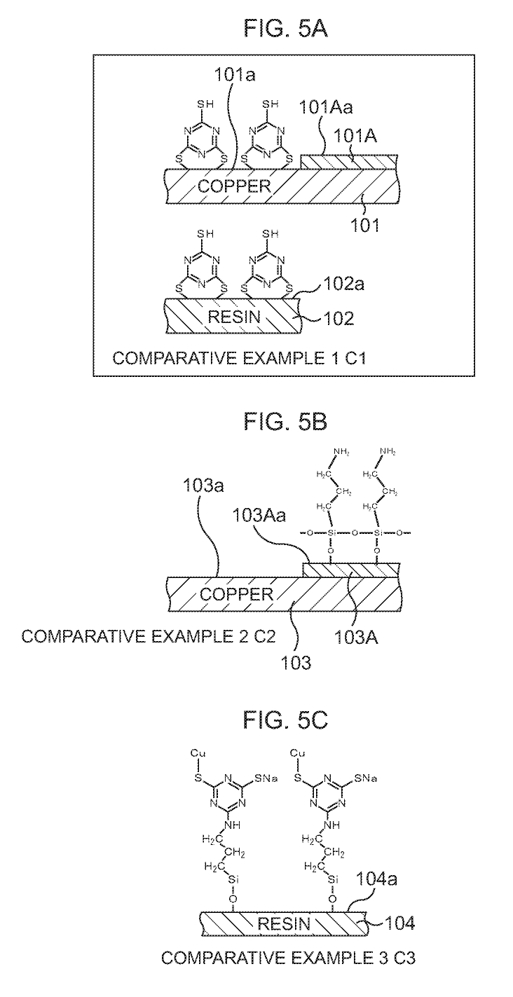

In Comparative Example 1, a joined body C1 produced based on Patent Document 1 is exemplified. In this example, as illustrated in FIG. 5A, a copper plate 101 and a resin layer 102 are immersed in a triazine thiol solution to form a triazine thiol film on a base surface 101a and a surface 102a. In this case, similarly to this embodiment, the base surface 101a of the copper plate 101 in contact with air causes formation of a copper oxide film 101A on part thereof, and the triazine thiol film is not formed on a surface 101Aa of the copper oxide film 101A. Therefore, adhesiveness between the copper plate 101 and the resin is weak to become insufficient.

### Comparative Example 2

In Comparative Example 2, a copper plate C2 produced based on Patent Document 2 is exemplified. In this example, a surface of a copper plate 103 is subjected to oxidation treatment and sequentially subjected to the silane coupling agent treatment. In this case, the silane coupling agent is not bonded to a base surface 103a not subjected to sufficient oxidation treatment. In consideration of such a case, as illustrated in FIG. 5B, this example presents the copper plate 103 in which the silane coupling agent is bonded to only a surface 103Aa of a copper oxide film 103A formed on part of the base surface 103a.

### Comparative Example 3

In Comparative Example 3, a resin layer C3 produced based on Patent Document 3 is exemplified. In this example, in a triazine thiol derivative having an alkoxysilyl group and a thiol group, silanol groups are formed by hydrolyzing alkoxysilyl groups of metal fine particles covering the triazine thiol derivative at thiol group portions. As illustrated in FIG. 5C, these silanol groups are chemically bonded to a surface 104a of a resin layer 104 of a base intended to form metal wiring.

### Comparative Example 4

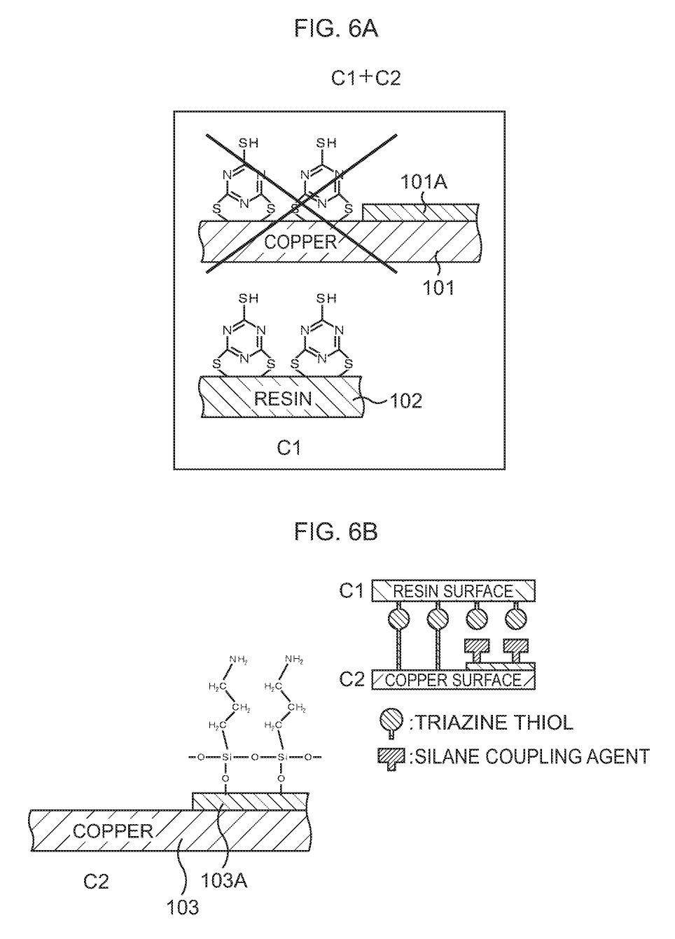

In Comparative example 4, a joined body produced by combining part of the joined body C1 in Comparative Example 1 and the copper plate 103 corresponding to the copper plate C2 in Comparative Example 2 is exemplified. In this example, as illustrated in FIG. 6A, the resin layer 102 of the joined body C1 and the copper plate 103 are joined to each other. In this case, as illustrated in FIG. 6B, thiol groups (—SH) of the resin layer 102 are bonded to the base surface 103a of the copper plate 103, but thiol groups (—SH) of the resin layer 102 are not bonded to amino groups (—NH₂) of the copper plate 103. Thus, the copper plate 103 and the resin layer 102 are only partially joined to each other, and the adhesiveness therebetween is weak to become insufficient.

### Comparative Example 5

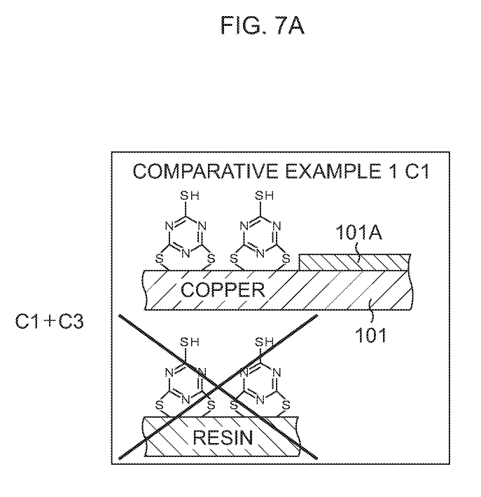

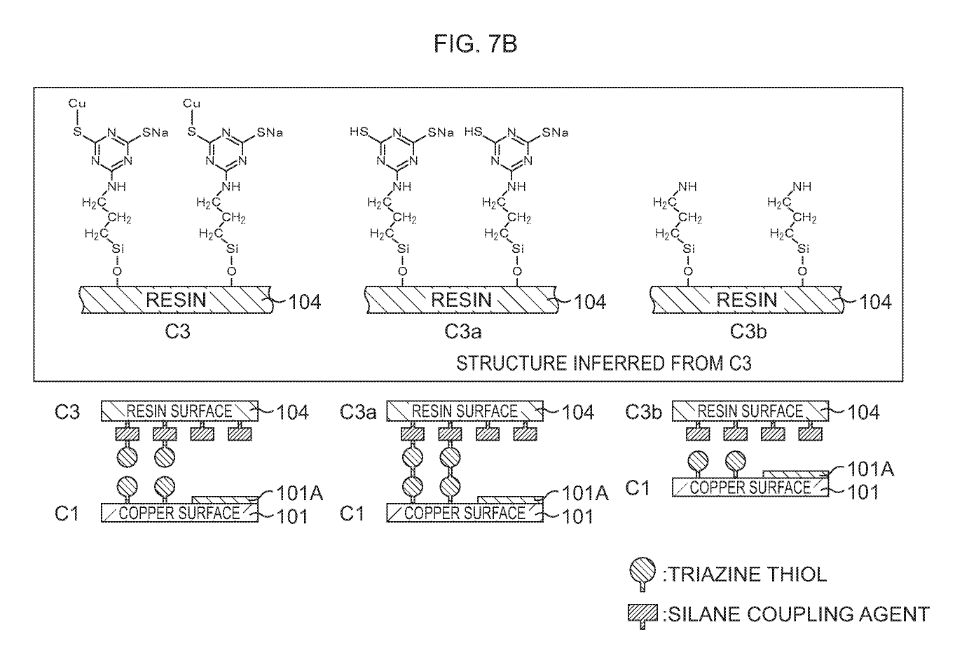

In Comparative Example 5, a joined body produced by combining part of the joined body C1 in Comparative Example 1 and the resin layer 104 corresponding to the resin layer C3 in Comparative Example 3 is exemplified. In this example, as illustrated in FIG. 7A, the copper plate 101 of the joined body C1 and the resin layer 104 are joined to each other. As the resin layer 104, the resin layer C3, and a resin layer C3a and a resin layer C3b which have structures inferred from the resin layer C3 are prepared.

FIG. 7B illustrates joint results.

When the copper plate 101 and the resin layer C3 are joined to each other, thiol groups (—SH) of the copper plate 101 are not bonded to terminal ends of the resin layer C3, and terminal ends of the resin layer C3 are not bonded to the copper oxide film 101A of the copper plate 101. Thus, no joint between the copper plate 101 and the resin layer C3 is obtained.

When the copper plate 101 and the resin layer C3a are joined to each other, the thiol groups (—SH) of the copper plate 101 are bonded to thiol groups (—SH) of the resin layer C3a, but terminal ends of the resin layer C3a are not bonded to the copper oxide film 101A of the copper plate 101. Thus, the copper plate 101 and the resin layer C3a are only partially joined to each other, and the adhesiveness therebetween is weak to become insufficient.

When the copper plate 101 and the resin layer C3b are joined to each other, the thiol groups (—SH) of the copper plate 101 are not bonded to terminal ends of the resin layer C3b, and terminal ends of the resin layer C3b are not bonded to the copper oxide film 101A of the copper plate 101. Thus, no joint between the copper plate 101 and the resin layer C3b is obtained.

### Comparative Example 6

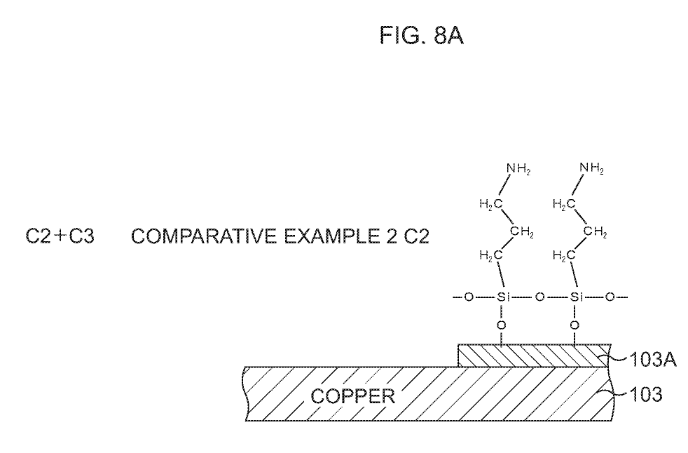

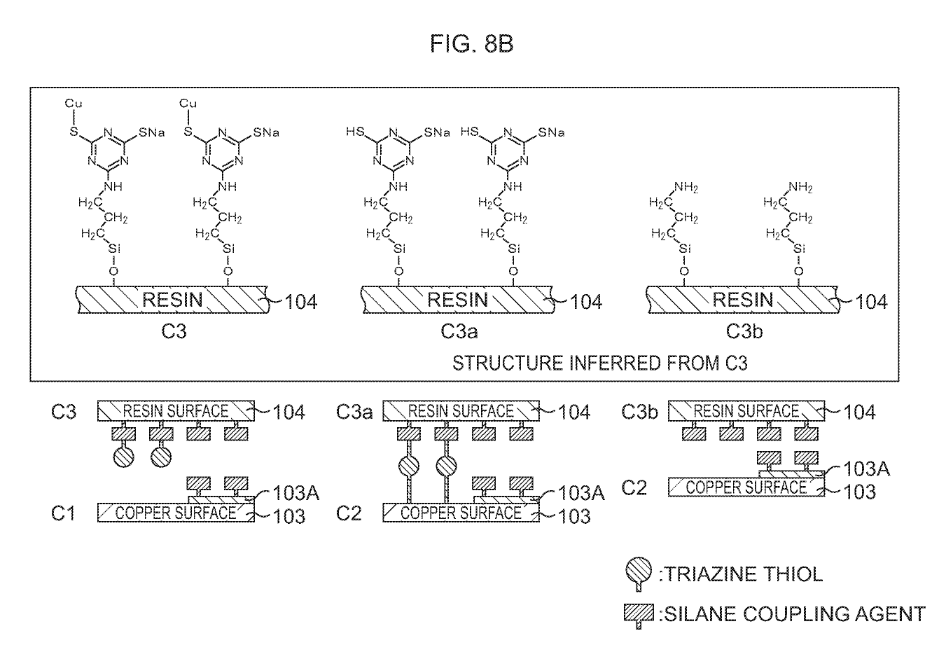

In Comparative Example 6, a joined body produced by combining the copper plate 103 corresponding to the copper plate C2 in Comparative Example 2 and the resin layer 104 corresponding to the resin layer C3 in Comparative Example 3 is exemplified. In this example, as illustrated in FIG. 8A, the copper plate 103 and the resin layer 104 are joined to each other. As the resin layer 104, the resin layer C3, and the resin layer C3a and the resin layer C3b which have the structures inferred from the resin layer C3 are prepared.

FIG. 8B illustrates joint results.

When the copper plate 103 and the resin layer C3 are joined to each other, the amino groups (—NH₂) of the copper oxide film 103A of the copper plate 103 are not bonded to terminal ends of the resin layer C3, and terminal ends of the resin layer C3 are not bonded to the base surface 103a of the copper plate 103. Thus, no joint between the copper plate 103 and the resin layer C3 is obtained.

When the copper plate 103 and the resin layer C3a are joined to each other, the thiol groups of the resin layer C3a are bonded to the base surface 103a of the copper plate 103, but the amino groups (—NH₂) of the copper oxide film 103A of the copper plate 103 are not bonded to terminal ends of the resin layer C3a. Thus, the copper plate 103 and the resin layer C3a are only partially joined to each other, and the adhesiveness therebetween is weak to become insufficient.

When the copper plate 103 and the resin layer C3b are joined to each other, the amino groups (—NH₂) of the copper oxide film 103A of the copper plate 103 are not bonded to amino groups (—NH₂) of the resin layer C3b. Similarly, amino groups (—NH₂) of the resin layer C3b are not bonded to the base surface 103a of the copper plate 103. Thus, no joint between the copper plate 103 and the resin layer C3b is obtained.

### Comparative Example 7

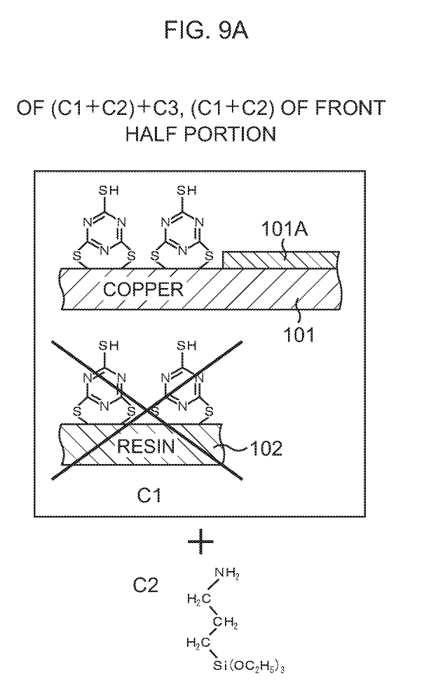

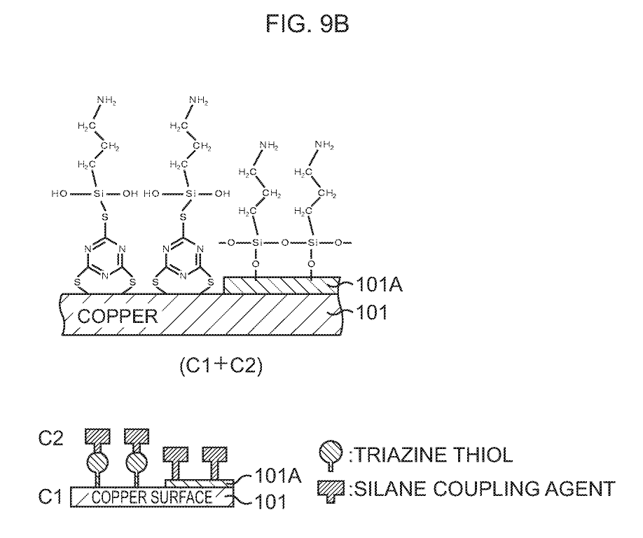

In Comparative Example 7, a joined body produced by combining part of the joined body C1 in Comparative Example 1, the silane coupling agent treatment in Comparative Example 2, and the resin layer 104 corresponding to the resin layer C3 in Comparative Example 3 is exemplified. In this example, first, as illustrated in FIG. 9A, the copper plate 101 of the joined body C1 is subjected to the silane coupling agent treatment in Comparative Example 2. At this time, as illustrated in FIG. 9B, a silane coupling agent is bonded to triazine thiol of base surface 101a of the copper plate 101, and the silane coupling agent is bonded to the copper oxide film 101A of the copper plate 101. The copper plate 101 at this time is referred to as a copper plate C1+C2.

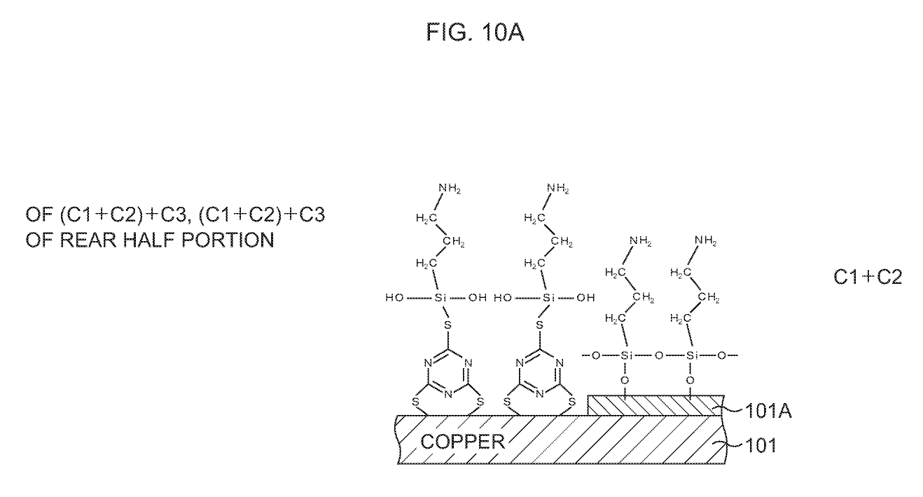

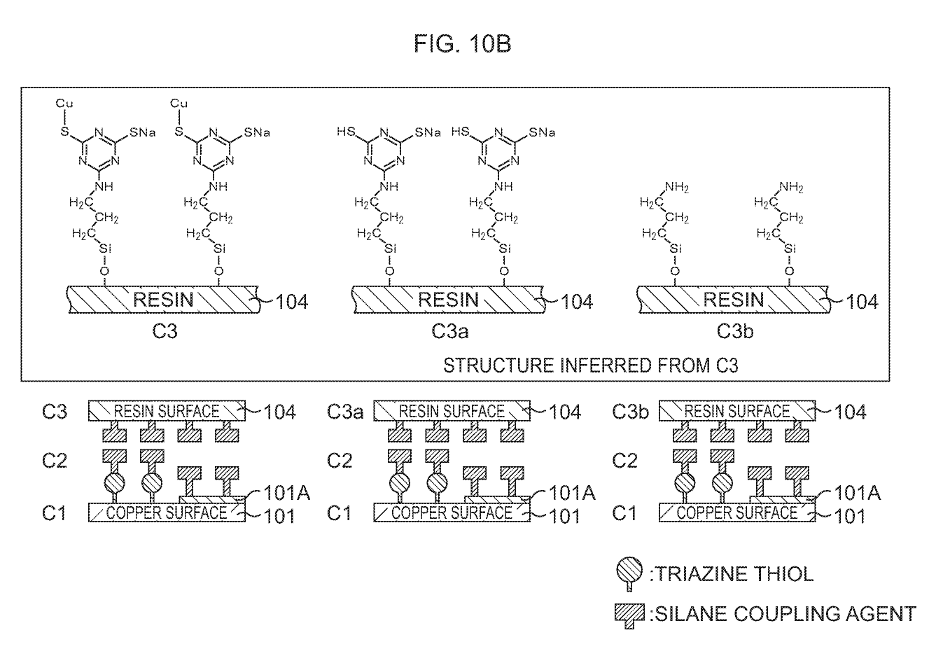

Sequentially, as illustrated in FIG. 10A, the copper plate C1+C2 and the resin layer 104 are joined to each other. As the resin layer 104, the resin layer C3, and the resin layer C3a and the resin layer C3b which have the structures inferred from the resin layer C3 are prepared.

FIG. 10B illustrates joint results.

When the copper plate C1+C2 and the resin layer C3 are joined to each other, both amino groups (—NH₂) of the base surface 101a of the copper plate C1+C2 and amino groups (—NH₂) of the copper oxide film 101A are not bonded to terminal ends of the resin layer C3. Thus, no joint between the copper plate C1+C2 and the resin layer C3 is obtained.

When the copper plate C1+C2 and the resin layer C3a are joined to each other, both the amino groups (—NH₂) of the base surface 101a of the copper plate C1+C2 and the amino groups (—NH₂) of the copper oxide film 101A are not bonded to terminal ends of the resin layer C3a. Thus, no joint between the copper plate C1+C2 and the resin layer C3a is obtained.

When the copper plate C1+C2 and the resin layer C3b are joined to each other, both the amino groups (—NH₂) of the base surface 101a of the copper plate C1+C2 and the amino groups (—NH₂) of the copper oxide film 101A are not bonded to the amino groups (—NH₂) of the resin layer C3a. Thus, no joint between the copper plate C1+C2 and the resin layer C3b is obtained.

As explained above, according to this embodiment, at a time of joining the copper plate 1 and the resin layer 2, even though the copper oxide film 1A is formed on part of the joint surface of the copper plate 1, both the base surface 1a and the copper oxide film 1A of the copper plate 1, and the resin layer 2 are molecularly joined securely to each other. This makes it possible to achieve a strong joint of the copper plate 1 and the resin layer 2 and obtain a joined body having high reliability.

### Second Embodiment

In this embodiment, a cooling system of electronic equipment in which the joined body according to the first embodiment is applied to a cooling plate is disclosed.

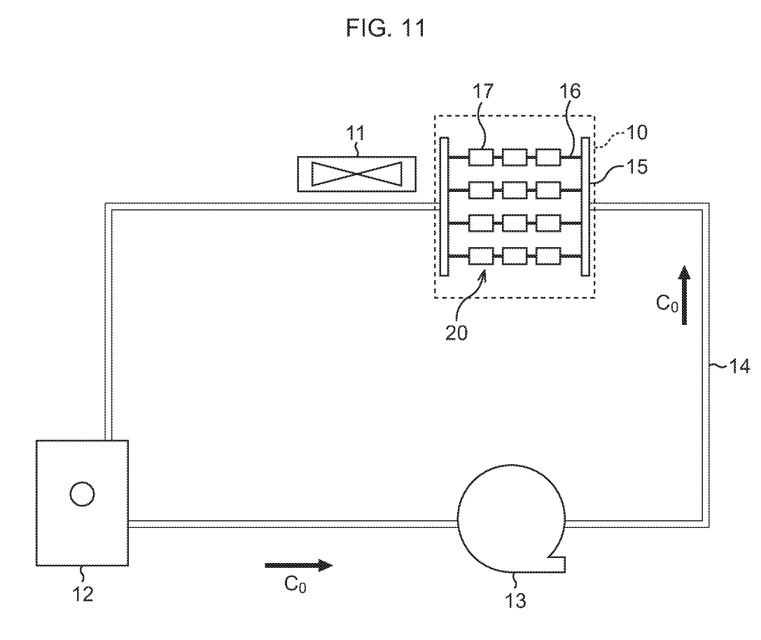

FIG. 11 is a schematic view illustrating a schematic configuration of a cooling device of the electronic equipment according to a second embodiment.

This cooling device is the one for cooling an electronic device 20 such as a server and is constituted by a cooling section 10, a heat exchanger 11, a tank 12 for a cooling liquid, and a drive pump 13 being connected to a circulation line 14. A cooling liquid C₀ in the tank 12 is circulated through the circulation line 14 by driving force of the drive pump 13, and the electronic device 20 is cooled by the cooling section 10.

Semiconductor devices such as LSI including an electronic component, for example a CPU are mounted on the electronic device 20.

The cooling section 10 includes a copper manifold 15 for dividing flow of the cooling liquid C₀, resin tubes 16 through which the cooling liquid C₀ going out of the copper manifold 15 passes, and cooling plates 17 to which the resin tubes 16 are connected.

The cooling plate 17 is provided for each of the semiconductor devices such as the LSI mounted on the electronic device 20. Each of the semiconductor devices is cooled individually by the cooling plate 17.

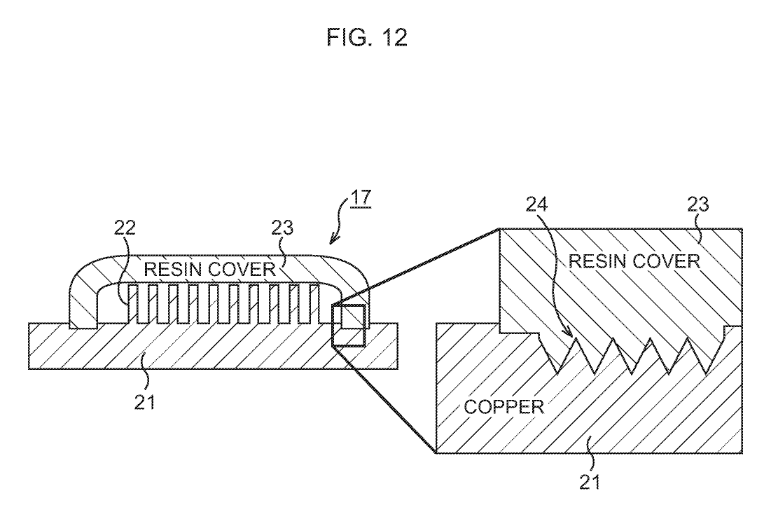

FIG. 12 illustrates a schematic configuration of the cooling plate 17. The cooling plate 17 is constituted by including a copper base plate 21 which is thermally connected to the semiconductor device, copper fins 22 which are formed on a surface of the copper base plate 21, and a resin cover 23 which covers the copper fins 22 above the copper base plate 21 and in which the cooling liquid is supplied to an inner space.

In the cooling plate 17, the first embodiment is applied to a joint of the copper base plate 21 and the resin cover 23. A joint surface of the copper base plate 21 to the resin cover 23 is formed as an anchor portion 24 by forming minute concavities and convexities by surface roughening treatment. In the anchor portion 24, the copper base plate 21 and the resin cover 23 are molecularly joined to each other by part of the resin of the resin cover 23 entering the concavities and the convexities. Similarly to FIG. 2C of the first embodiment, even though a copper oxide film is formed on part of the copper base plate 21 in the joint surface, a perfect molecular joint in the entire surface of the joint surface, namely both a base surface and the resin cover 23, and the copper oxide film and the resin cover 23 is obtained. This achieves very high joint strength of the copper base plate 21 and the resin cover 23.

The cooling liquid C₀ is not particularly limited, but the one which is produced by dissolving an inhibitor (corrosion inhibitor) in pure water is used in this embodiment. As the inhibitor, it is suitable to use benzotriazole effective in corrosion control of a copper material. In this case, an inhibitor concentration may be set to about 100 ppm, for example. Using the inhibitor for copper prevents portions in contact with the cooling liquid C₀ in the Cu manifold 15 and the copper base plate 21 of the cooling plate 17 from being eluted by the cooling liquid C₀.

The cooling liquid C₀ warmed by the electronic device 20 enters the heat exchanger 11 provided on the circulation line 14 downstream from the electronic device 20. In the heat exchanger 11, the cooling liquid C₀ is air-cooled by a fan and heat of the cooling liquid C₀ is radiated outside. The copper material is used for the heat exchanger 11 which is a portion in contact with the cooling liquid C₀, but adding the inhibitor for copper in the cooling liquid C₀ as described above makes it possible to suppress corrosion of the heat exchanger 11 and prevent water from leaking in the heat exchanger 11.

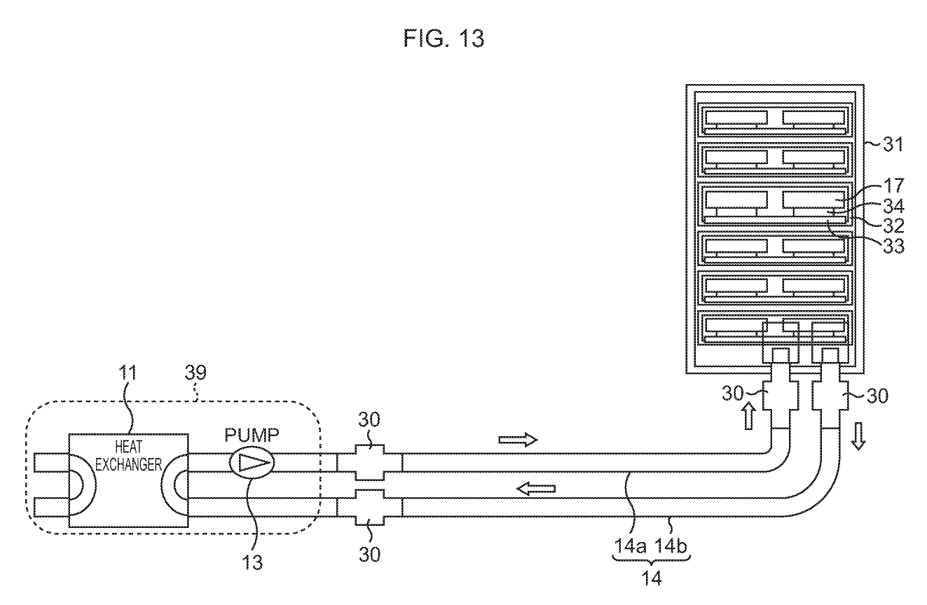

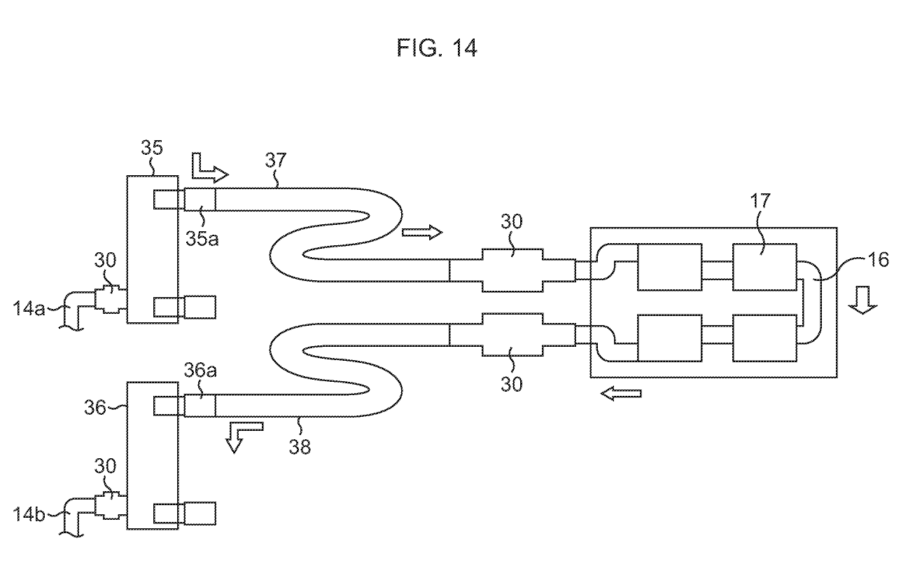

FIG. 13 and FIG. 14 illustrate specific examples of the cooling device in FIG. 11. The same constituent members as those in FIG. 11 are denoted by the same reference signs, and detailed explanations are omitted.

In the server, a plurality of, for example several tens of chassis 32 are stacked in a rack 31. In each of the chassis 32, many central processing units (CPU) 34 are provided on a wiring board 33, and the cooling plate 17 is placed for each of the CPUs 34.

The circulation line 14 has a first rack hose 14a and a second rack hose 14b each of whose one end is connected to the rack 31 by each of metal couplers 30, and the first rack hose 14a supplies the cooling liquid to the rack 31 and the second rack hose 14b discharges the used cooling liquid from the rack 31.

As not illustrated in FIG. 13 but illustrated in FIG. 14, a first main pipe 35 and a second main pipe 36 are provided in the rack 31. One end of the first rack hose 14a is connected to the first main pipe 35 and one end of the second rack hose 14b is connected to the second main pipe 36, respectively, by the metal couplers 30.

One resin tube 16 is connected to each of the cooling plates 17 in the chassis 32, the cooling liquid is supplied from one end of the resin tube 16, and the used cooling liquid is discharged from the other end of the resin tube 16. By this circulation of the cooling liquid, each of the CPUs 34 on which each of the cooling plates 17 is disposed is appropriately cooled.

The first main pipe 35 has a plurality of (illustrated example illustrates only two) terminals 35a corresponding to the chassis 32. One end of a first flexible hose 37 is connected to each of the terminals 35a by the metal coupler 30, and the other end of the first flexible hose 37 is connected to one end of the resin tube 16 by the metal coupler 30.

The second main pipe 36 has a plurality of (illustrated example illustrates only two) terminals 36a corresponding to the chassis 32. One end of a second flexible hose 38 is connected to each of the terminals 36a by the metal coupler 30, and the other end of the second flexible hose 38 is connected to one end of the resin tube 16 by the metal coupler 30.

The respective other ends of the first rack hose 14a and the second rack hose 14b are connected to a coolant distribution unit (CDU) 39 by the metal couplers 30. The CDU 39 doubles as the tank 12 and has the heat exchanger 11 and the drive pump 13 inside the CDU 39.

As explained above, according to this embodiment, at a time of joining the copper base plate 21 and the resin cover 23, even though the copper oxide film is formed on part of the joint surface of the copper base plate 21, the molecular joint is obtained on the entire surface of the joint surface. That is, the secure molecular joint is obtained between both the base surface and the copper oxide film of the copper base plate 21, and the resin cover. This achieves a strong joint of the copper base plate 21 and the resin cover 23, and achieves the cooling device having high reliability, which includes the cooling plate 17 which is as lightweight as possible and allows secure prevention of leakage of cooling water.

### EXAMPLES

### First Example

In a first example, regarding a cooling plate which is a component of a cooling device according to the second embodiment, a specific example with regard to a manufacturing method thereof is explained.

First, a copper base plate provided with copper fins is prepared, and a portion other than a joint surface to a resin cover in the copper base plate is protected by a masking tape. Surface roughening treatment for the joint surface of the copper base plate is performed by immersing the base plate in a chemical solution (trade name AMALPHA A-10201 of MEC Co., Ltd.) for five minutes.

Sequentially, with respect to the copper base plate, water washing, alkaline cleaning, (5% NaOH aqueous solution, immersion treatment for 20 seconds), water washing, neutralization treatment (immersion treatment in 5% H₂SO₄ aqueous solution for 20 seconds), and water washing are performed.

Sequentially, the copper base plate is immersed in an aqueous solution of 0.1 mol/L of 2,4,6-trimercapto-1,3,5-triazine monosodium salt (trade name Santhiol N-1 made by SANKYO KASEI Co., Ltd.) for five minutes.

Sequentially, the copper base plate is immersed in a 3-aminopropyltriethoxysilane (trade name KBE903 made by Shin-Etsu Chemical Co., Ltd.) aqueous solution of 0.05 mol/L as a silane coupling agent. Thereafter, the copper base plate is dried at 100° C. for 30 minutes.

A polypropylene resin (trade name FP994 made by Daicel polymer Ltd.) is used to be molded into a cover shape, thereby forming a resin cover.

Sequentially, a joint surface of the resin cover to the copper base plate is subjected to UV ozone irradiation for ten minutes.

The resin cover and the copper base plate are subjected to thermocompression bonding (hot press) on condition that a pressure-bonding temperature is set to 170° C., a pressure is set to 0.5 MPa, and a pressure-bonding time is set to 60 seconds, to be integrated, thereby forming a cooling plate.

### Second Example

In a second example, a joint strength test and a water pressure resistance test are performed. In the joint strength test, regarding the cooling plate which is the component of the cooling device according to the second embodiment, joint strength of the copper base plate and the resin cover is examined using samples for measurement. In the water pressure resistance test, water is filled inside produced cooling plates, and water pressure resistance is examined using a hydraulic pump.

The samples for measurement are produced under the same condition as that in the first example. Here, the samples for measurement which are subjected to reactive film treatment (triazine thiol treatment) in which a triazine thiol derivative is used are regarded as “Example” (Examples 1 to 8), and the samples for measurement which are not subjected to the triazine thiol treatment are regard as “Comparative Example” (Comparative Examples 8 to 15).

Measurement of the joint strength is performed specifically by the following method.

As a copper member, a plate material (oxygen-free copper: C1020) of 50 mm×25 mm×1.5 mm thickness is used.

As a resin member, a plate material (trade name FP994 made by Daicel Polymer Ltd.) molded into 25 mm×25 mm×2 mm thickness is used.

Except that a copper member and a resin member are replaced with the above-described copper member and resin member, respectively, the same as the first embodiment and the first example, surface roughening treatment, reactive film treatment in which a triazine thiol derivative is used, silane coupling agent treatment, resin surface treatment (UV ozone treatment here), and thermocompression bonding are performed appropriately to produce each of the samples for measurement.

An area of a joint surface of the copper member and the resin member is 312.5 mm² (=25 mm×12.5 mm).

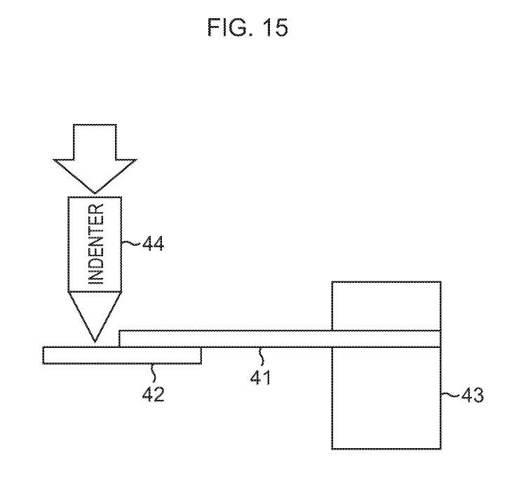

The joint strength is measured using a measuring device illustrated in FIG. 15. As the measuring device, 5878 Micro Tester, as a trade name, made by Instron Corporation is used. Specifically, a copper member 41 is fixed to a fixture 43 so that the copper member 41 is placed on an upper side and a resin member 42 is placed on a lower side in the joint surface. At a position of 5 mm from an end portion of the joint surface, an indenter 44 is pressed to an upper surface of the resin member 42 and the indenter 44 is pressed down at a press-down rate of 1 mm/sec. Pressing force at that time is evaluated as the joint strength (MPa). The joint strength (MPa) is evaluated as a value obtained by dividing a press-peel load (maximum load) (N) found from a load curve at a time of pressing by the joint area.

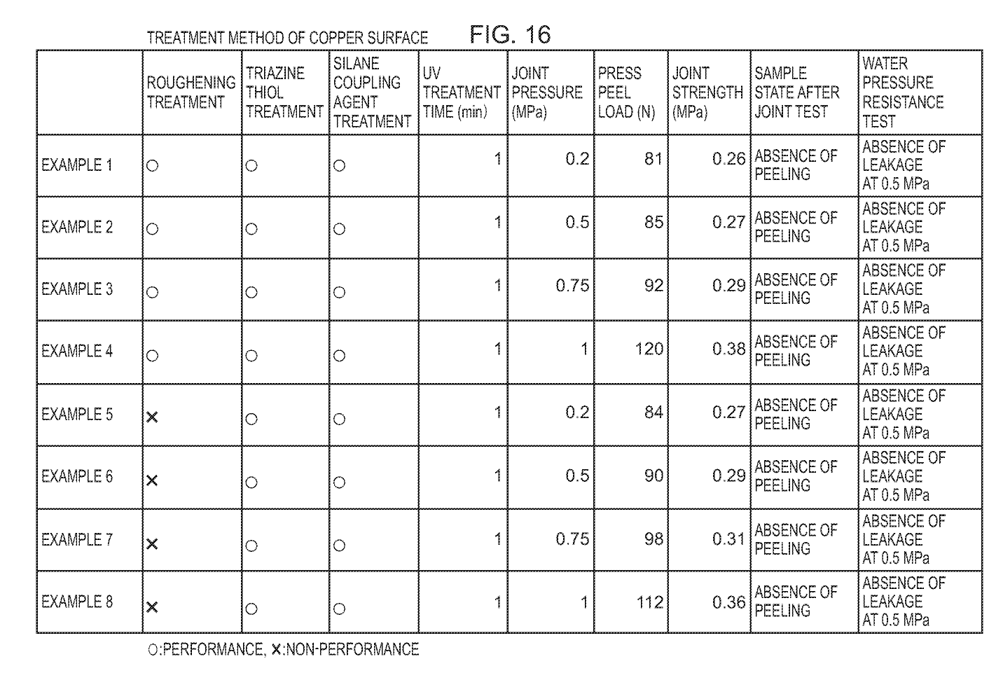

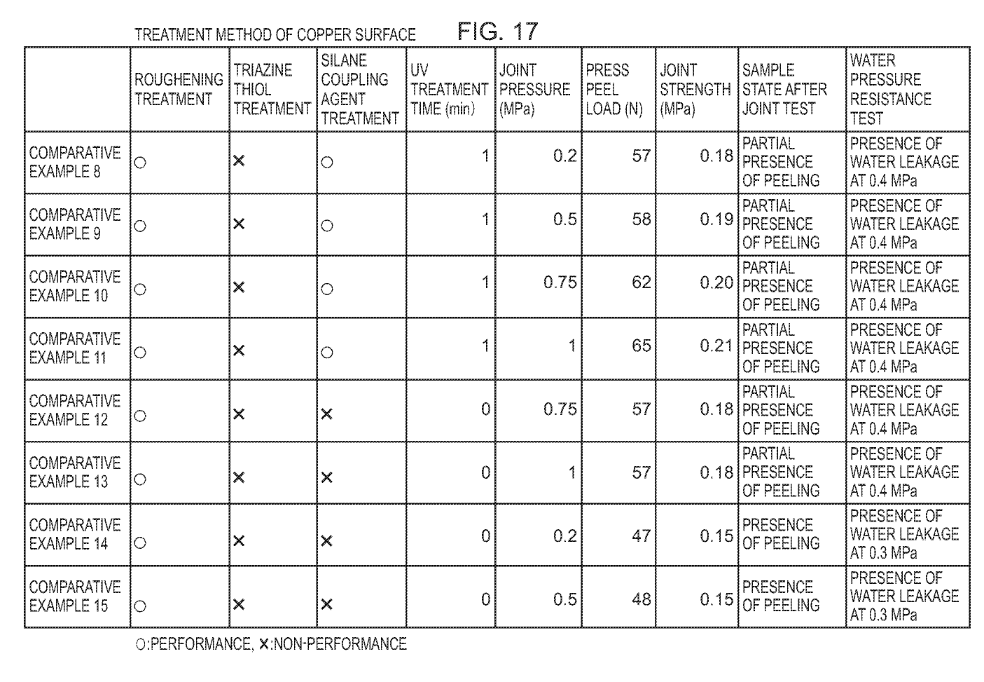

The tables in FIG. 16 and FIG. 17 illustrate evaluation results.

Regarding the samples for measurement of Examples 1 to 4, the surface roughening treatment, the reactive film treatment in which the triazine thiol derivative is used, and the silane coupling agent treatment are performed, and joint pressures are set to 0.2 MPa to 1 MPa.

In the samples for measurement of Examples 1 to 4, the maximum loads are 81 N to 120 N and the joint strengths are 0.26 to 0.38 MPa. In these samples for measurement, resin members do not peel off copper members and deformation is seen in the resin members as modes after the maximum loads.

In cooling plates produced corresponding to the samples for measurement of Examples 1 to 4, a change such as water leakage does not occur even in the test at a water pressure of 0.5 MPa for five minutes.

Regarding the samples for measurement of Examples 5 to 8, the reactive film treatment in which the triazine thiol derivative is used and the silane coupling agent treatment are performed but the surface roughening treatment is not performed, and the joint pressures are set to 0.2 MPa to 1 MPa.

In the samples for measurement of Examples 5 to 8, the maximum loads are 84 N to 112 N and the joint strengths are 0.27 MPa to 0.36 MPa. In these samples for measurement, resin members do not peel off copper members and deformation is seen in the resin members as modes after the maximum loads.

In cooling plates produced corresponding to the samples for measurement of Examples 5 to 8, a change such as the water leakage does not occur even in the test at a water pressure of 0.5 MPa for five minutes.

Regarding the samples for measurement of Comparative Examples 8 to 11, the surface roughening treatment and the silane coupling agent treatment are performed but the reactive film treatment in which the triazine thiol derivative is used is not performed, and the joint pressures are set to 0.2 MPa to 1 MPa.

In the samples for measurement of Comparative Examples 8 to 11, interfacial peeling occurs on part of joint surfaces of resin members and copper members. The maximum loads at that time are 57 N to 65 N and the joint strengths are 0.18 to 0.21 MPa.

In cooling plates produced corresponding to the samples for measurement of Comparative Examples 8 to 11, the water leakage occurs from the joint surfaces of the resin members and the copper members by application of a water pressure of 0.4 MPa.

Regarding the samples for measurement of Comparative Examples 12 to 15, the surface roughening treatment is performed but the reactive film treatment in which the triazine thiol derivative is used and the silane coupling agent treatment are not performed. The joint pressures are made large (0.75 MPa to 1 MPa) in Comparative Examples 12 to 13 and the joint pressures are made small (0.2 MPa to 0.5 MPa) in Comparative Examples 14 to 15.

In the samples for measurement of Comparative Examples 12 to 13, the interfacial peeling occurs on part of joint surfaces of resin members and copper members. The maximum load at that time is 57 N and the joint strength is 0.18 MPa.

In the samples for measurement of Comparative Examples 14 to 15, the interfacial peeling occurs on joint surfaces of resin members and copper members. The maximum loads at that time are 47 N to 48 N and the joint strength is 0.15 MPa.

In cooling plates produced corresponding to the samples for measurement of Comparative Examples 12 to 13, the water leakage occurs from the joint surfaces of the resin members and the copper members by application of a water pressure of 0.4 MPa.

In cooling plates produced corresponding to the samples for measurement of Comparative Examples 14 to 15, the water leakage occurs from the joint surfaces of the resin members and the copper members by application of a water pressure of 0.3 MPa.

As described above, according to the second example, regarding the cooling plate which is a component of the cooling system according to the second embodiment, the following is confirmed with respect to the joint of the copper base plate and the resin cover.

In the joint of the copper base plate and the resin cover, by performing the reactive film treatment in which the triazine thiol derivative is used and the silane coupling agent treatment, sufficiently high joint strength is obtained without occurrence of peeling in a joint portion thereof.

According to the above-described aspect, at a time of joining copper and resin, even though an oxide film is formed on part of a joint surface of the copper, it is possible to obtain a joined body having high reliability by molecularly joining both a base surface and the oxide film of the copper, and the resin securely and achieving a strong joint of the copper and the resin.

According to the above-described aspect, at a time of joining a copper base plate and a resin cover, even though an oxide film is formed on part of a joint surface of the copper base plate, both a base surface and an oxide film of the copper base plate, and the resin cover are molecularly joined securely to each other. This makes it possible to achieve a strong joint of the copper base plate and the resin cover and obtain a cooling device having high reliability, which includes a cooling plate which is as lightweight as possible and allows secure prevention of leakage of a cooling liquid.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

According to the embodiments, at a time of joining copper and resin, even though an oxide film is formed on part of a joint surface of the copper, it is possible to obtain a joined body having high reliability by molecularly joining both a base surface and the oxide film of the copper, and the resin securely and achieving a strong joint of the copper and the resin.

According to the embodiments, at a time of joining a copper base plate and a resin cover, even though an oxide film is formed on part of a joint surface of the copper base plate, both a base surface and the oxide film of the copper base plate, and the resin cover are molecularly joined securely to each other. This makes it possible to achieve a strong joint of the copper base plate and the resin cover and obtain a cooling device having high reliability, which includes a cooling plate which is as lightweight as possible and allows secure prevention of leakage of cooling water.

What is claimed is:

1. A joined body comprising
copper and resin,
wherein in a joint surface of the copper to the resin, a triazine thiol derivative, or the triazine thiol derivative and a silane coupling agent are bonded to a base surface, and the silane coupling agent is bonded to an oxide film formed on part of the joint surface, respectively, and
wherein the copper and the resin are molecularly joined to each other.

2. The joined body according to claim 1,
wherein concavities and convexities are formed on the joint surface of the copper, and
wherein the copper and the resin are molecularly joined to each other by part of the resin entering the concavities and the convexities.

3. The joined body according to claim 1,
wherein the resin is a thermoplastic resin.

4. The joined body according to claim 1,
wherein the silane coupling agent includes at least one type selected from a group constituted of an amino group, a mercapto group, an epoxy group, an imidazole group, and a dialkylamino group in a molecular.

5. A manufacturing method of a joined body comprising
molecularly joining
copper in which a triazine thiol derivative, or the triazine thiol derivative and a silane coupling agent are bonded to a base surface in a joint surface and the silane coupling agent is bonded to an oxide film formed on part of the joint surface, respectively, and
resin
by bringing the copper and the resin in contact with each other.

6. The manufacturing method of the joined body according to claim 5,
wherein the joint surface of the copper is subjected to roughening treatment to form concavities and convexities, and
wherein the copper and the resin are molecularly joined to each other by part of the resin entering the concavities and the convexities.

7. The manufacturing method of the joined body according to claim 5,
wherein the resin is a thermoplastic resin, and a hydroxyl group or a carboxyl group is bonded to a surface, and
wherein the molecular joint is made by thermocompression bonding the copper and the resin.

8. The manufacturing method of the joined body according to claim 7,
wherein the hydroxyl group or the carboxyl group is bonded to a surface of the resin by subjecting the resin to surface treatment.

9. The manufacturing method of the joined body according to claim 8,
wherein the surface treatment is one treatment selected from UV ozone treatment, oxygen plasma treatment, alkaline cleaning, and boiling treatment when the hydroxyl group is bonded to the surface of the resin, and one type of treatment selected from the UV ozone treatment, the oxygen plasma treatment, and corona discharge treatment when the carboxyl group is bonded to the surface of the resin.

10. The manufacturing method of the joined body according to claim 5,
wherein the silane coupling agent includes at least one type selected from a group constituted of an amino group, a mercapto group, an epoxy group, an imidazole group, and a dialkylamino group in a molecule of the silane coupling agent.

11. A cooling device comprising a cooling plate comprising:
a copper base plate to which an electronic component is thermally connected; and
a resin cover which covers above the copper base plate and in which a cooling liquid is supplied to an inner space, wherein the electronic component is cooled by circulating the cooling liquid,
wherein in a joint surface of the copper base plate to the resin cover, a triazine thiol derivative, or the triazine thiol derivative and a silane coupling agent are bonded to a base surface, and the silane coupling agent is bonded to an oxide film formed on part of the joint surface, respectively, and
wherein the copper base plate and the resin cover are molecularly joined to each other.

12. The cooling device according to claim 11,
wherein concavities and convexities are formed on the joint surface of the copper base plate, and
wherein the copper base plate and the resin cover are molecularly joined to each other by part of the resin cover entering the concavities and the convexities.

13. The cooling device according to claim 12,
wherein the resin cover is formed of a thermoplastic resin.

14. The cooling device according to claim 11,
wherein the silane coupling agent includes at least one type selected from a group constituted of an amino group, a mercapto group, an epoxy group, an imidazole group, and a dialkylamino group in a molecule.

15. An electronic equipment comprising:
a cooling device which includes a cooling plate including a copper base plate to which an electronic component is thermally connected and a resin cover which covers above the copper base plate and in which a cooling liquid is supplied to an inner space, and in which the electronic component is cooled by circulating the cooling liquid; and
an electronic device which includes the electronic component,
wherein in a joint surface of the copper base plate to the resin cover, a triazine thiol derivative, or the triazine thiol derivative and a silane coupling agent are bonded to a base surface and the silane coupling agent is bonded to an oxide film formed on part of the joint surface, respectively, and
wherein the copper base plate and the resin cover are molecularly joined to each other.

16. The electronic equipment according to claim 15,
wherein concavities and convexities are formed on the joint surface of the copper base plate, and
wherein the copper base plate and the resin cover are molecularly joined to each other by part of the resin cover entering the concavities and the convexities.

17. The electronic equipment according to claim 16,
wherein the resin cover is formed of a thermoplastic resin.

18. The electronic equipment according to claim 15,
wherein the silane coupling agent includes at least one type selected from a group constituted of an amino group, a mercapto group, an epoxy group, an imidazole group, and a dialkylamino group in a molecule.
